(19) United States
(12) Patent Application Publication
(10) Pub. No.: US 2025/0324898 A1
(43) Pub. Date: Oct. 16, 2025

(54) MANUFACTURING METHOD AND MANUFACTURING APPARATUS FOR MANUFACTURING PEROVSKITE-TYPE SOLAR CELL

(71) Applicant: TOYOTA JIDOSHA KABUSHIKI KAISHA, Toyota-shi (JP)

(72) Inventor: Yoichi AOKI, Toyota-shi (JP)

(73) Assignee: TOYOTA JIDOSHA KABUSHIKI KAISHA, Toyota-shi (JP)

(21) Appl. No.: 19/005,025

(22) Filed: Dec. 30, 2024

(30) Foreign Application Priority Data
Apr. 12, 2024 (JP) 2024-064375

(51) Int. Cl. H10K 71/13; H10F 71/00; H10K 71/15; H10K 85/50

(52) U.S. Cl. CPC H10K 71/135; H10F 71/00; H10K 71/15; H10K 85/50

(57) ABSTRACT

The present disclosure relates to a manufacturing method of a perovskite-type solar cell, and an apparatus for manufacturing a perovskite-type solar cell, including a step of applying a precursor solution of a perovskite compound as a droplet, and a step of applying a poor solvent as a droplet until a droplet of the precursor solution adhered to a coating surface is combined with a droplet of another precursor solution, and a manufacturing device including a precursor solution applying unit, a poor solvent applying unit, and a control unit.

### CROSS-REFERENCE TO RELATED APPLICATION

This application claims priority to Japanese Patent Application No. 2024-064375 filed on Apr. 12, 2024, incorporated herein by reference in its entirety.

### BACKGROUND

### 1. Technical Field

The present disclosure relates to a manufacturing method and a manufacturing apparatus for manufacturing a perovskite-type solar cell.

### 2. Description of Related Art

Solar cells are widely used as energy sources with low environmental loads. There is known, as one type of a solar cell, a perovskite-type solar cell in which a main component of a photoelectric conversion layer is a perovskite compound.

A manufacturing method for manufacturing a perovskite-type solar cell is described in Japanese Unexamined Patent Application Publication No. 2023-148126 (JP 2023-148126 A), for example. In this manufacturing method, after a material film of a perovskite thin film is applied, a gaseous or mist-like poor solvent is sprayed onto the material film of the perovskite thin film, such that the material film of the perovskite thin film dries and crystalizes. However, the present inventors have found a problem in that when the poor solvent is added to the material film of the perovskite thin film, the poor solvent is not sufficiently mixed with the material film, and as a result, film quality of the photoelectric conversion layer is impaired.

### SUMMARY

As described above, in conventional manufacturing of perovskite-type solar cells, there is a problem in that the film quality of the photoelectric conversion layer containing the perovskite compound is impaired. Accordingly, an object of the present disclosure is to provide a manufacturing method and a manufacturing apparatus for manufacturing a perovskite-type solar cell in which film quality of a photoelectric conversion layer is improved.

The present inventors have found that film quality of a photoelectric conversion layer containing a perovskite compound is improved by applying a poor solvent as droplets until droplets of a precursor solution of the perovskite compound is bound with droplets of another precursor solution and form a film, and thus the present disclosure was completed.

That is to say, the gist of the present disclosure is as follows.
(1) A manufacturing method for manufacturing a perovskite-type solar cell, the manufacturing method including applying a precursor solution of a perovskite compound as droplets, and applying a poor solvent as droplets, until droplets of the precursor solution adhering to an application face bind to droplets of another precursor solution.
(2) The manufacturing method according to the above (1), further including applying the precursor solution and the poor solvent by an inkjet method or a spray method.
(3) The manufacturing method according to the above (1) or (2), in which the poor solvent is one type or more selected from solvents of which a relative permittivity is 20 or lower and also a boiling point is 100° C. or higher.
(4) The manufacturing method according to any one of (1) to (3), in which a temperature of the precursor solution is 40° C. or higher, and a temperature of the application face is 60° C. or higher.
(5) A manufacturing apparatus for manufacturing a perovskite-type solar cell, the manufacturing apparatus including
a precursor solution applying unit that applies a precursor solution of a perovskite compound as droplets,
a poor solvent applying unit that applies a poor solvent as droplets, and
a control unit that controls the precursor solution applying unit and the poor solvent applying unit such that the poor solvent is applied as droplets, until droplets of the precursor solution adhering to an application face bind to droplets of another precursor solution.

According to the present disclosure, a manufacturing method and a manufacturing apparatus for manufacturing a perovskite-type solar cell, in which film quality of a photoelectric conversion layer is improved, can be provided.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic view of one embodiment of a manufacturing apparatus of the present disclosure;

FIG. 2 is an appearance photograph of the wet film of Example 1;

FIG. 3 is an external photograph of a wet film of Comparative Example 1; and

FIG. 4 is an appearance photograph of the wet film of Example 2.

### DETAILED DESCRIPTION OF EMBODIMENTS

Hereinafter, preferred embodiments of the present disclosure will be described in detail.

The present disclosure relates to a manufacturing method of a perovskite-type solar cell having a photoelectric conversion layer containing a perovskite compound. The manufacturing method of the solar cell of the present disclosure includes a step of applying a precursor solution of a perovskite compound as a droplet (precursor solution applying step) and a step of applying a poor solvent as a droplet (poor solvent applying step). In the present disclosure, in the poor solvent application step, by applying the poor solvent as droplets until the droplets of the precursor solution adhered to the application surface combine with the droplets of the other precursor solution, a uniform photoelectric conversion layer is obtained, and the film quality of the photoelectric conversion layer is improved.

In the precursor solution applying step of the manufacturing method of the present disclosure, the precursor solution of the perovskite compound is applied as a droplet. Here, the precursor solution refers to a solution containing a perovskite compound as a solute.

The perovskite compound is a compound having a perovskite-type crystal structure. The perovskite crystal structure typically consists of ions A, B and X. The perovskite-type crystal structure has a cubic unit cell, A is disposed at each apex of the cubic crystal, and B is disposed at the body center, and X is disposed at each face center of the cubic crystal. The fact that the compound has a perovskite-type crystal structure can be confirmed, for example, by X-ray diffraction measurement.

The perovskite compound can be represented by the following formula (1), for example.

ABX₃ (1)

Wherein A is a monovalent cation, B is a divalent cation, and X is a monovalent anion.

In one embodiment, in Formula (1), A is at least one selected from a monovalent organic ammonium ion, a monovalent amidinium-based ion, and a monovalent metal ion. Examples of the monovalent organic ammonium ion include CH₃NH₃⁺ (methylammonium ion: MA), C₂H₅NH₃⁺, C₃H₇NH₃⁺, and C₄H₉NH₃⁺. Examples of the monovalent amidinium-based ion include HC(NH₂)₂⁺ (formamidinium ion: FA). Examples of monovalent metallic ions include rubidium ions (Rb⁺) and cesium ions (Cs⁺). In Formula (1), A may be a combination of a monovalent organic ammonium ion, a monovalent amidinium-based ion, and a monovalent metal ion. In the formula (1), A is preferably MA, FA or Cs⁺, or a combination of two or three thereof. When A contains Rb⁺ or Cs⁺, the content of Rb⁺ or Cs⁺ relative to the total amount of A is usually 10 atomic % or less.

In one embodiment, in equation (1), B is a binary metal ion, e.g., a lead ion (Pb²⁺), a tin ion (Sn²⁺) and a combination thereof, more preferably a Pb²⁺.

In one embodiment, in Formula (1), X is a halogen ion. X is, for example, at least one selected from fluoride ion (F⁻), chloride ion (Cl⁻), bromide ion (Br⁻), and iodide ion (I⁻). X is preferably Cl⁻, Br⁻ and I⁻.

The precursor solution can be prepared by dissolving a perovskite compound, a solvent adduct of a perovskite compound, or a plurality of perovskite compound raw materials in an appropriate solvent. For example, when the perovskite compound is represented by the above-described formula (1), the precursor solution can be prepared by dissolving one or more compounds represented by the following formula (2) and one or more compounds represented by the following formula (3) in an appropriate solvent.

AX (2)

BX₂ (3)

As the solvent of the precursor solution, for example, a solvent having a relative permittivity of 30 or more can be used. In one embodiment, when the applying of the precursor solution is performed by the inkjet method, the solvent of the precursor solution is preferably a solvent having a boiling point of 100° C. or higher from the viewpoint of suppressing clogging of the inkjet nozzle. The solvent of the precursor solution is not particularly limited, and examples thereof include organic solvents such as N,N-dimethylformamide (DMF), dimethyl sulfoxide (DMSO), N-methylpyrrolidone (NMP), and γ-butyrolactone (GBL). As the solvent of the precursor solution, these solvents may be used alone, or two or more of them may be used in combination. In one embodiment, the solvents of the precursor solutions are DMF, DMSO, GBL and mixtures thereof.

As described above, in the precursor solution application step, the precursor solution of the perovskite compound is applied as a droplet to the application surface. In one embodiment, the application surface is the surface of a first carrier transport layer (e.g., a hole transport layer or an electron transport layer) described below for a perovskite-type solar cell. The application of the precursor solution as a droplet can be performed by, for example, a spin coating method, a slit coating method, an ink jet method, and a spray method, and an ink jet method and a spray method are preferable, and an ink jet method is more preferable.

As an application condition of the precursor solution, a condition normally used can be appropriately selected.

The precursor solution application step can be performed under a dry air atmosphere or an inert gas atmosphere. Examples of the inert gas include, but are not limited to, gases such as nitrogen and argon, and nitrogen gas is preferable from the viewpoint of availability and production cost.

In the precursor solution applying step, the temperature of the precursor solution is usually 25° C. or higher, preferably 40° C. or higher. The temperature of the precursor solution is usually 60° C. or lower, preferably 50° C. or lower. In the precursor solution applying step, the temperature of the coating surface is usually 20° C. or higher, preferably 40° C. or higher, and more preferably 60° C. or higher. The temperature of the application surface is usually 80° C. or lower, preferably 70° C. or lower. In a preferred embodiment, the temperature of the precursor solution is greater than or equal to 40° C. and the temperature of the application surface is greater than or equal to 60° C. In this embodiment, high quality perovskite crystals are formed.

In the poor solvent application step of the manufacturing method of the present disclosure, the poor solvent is applied to the droplets of the precursor solution as droplets until the droplets of the precursor solution adhered to the application surface combine with the droplets of the other precursor solution. The application of the poor solvent can promote the formation of crystal nuclei of the perovskite compound. In the manufacturing method of the present disclosure, the droplets of the precursor solution adhered to the coating surface are combined with the droplets of the other precursor solution and spread, and the droplets of the precursor solution and the droplets of the poor solvent are sufficiently mixed by applying the poor solvent as droplets before forming a film. Therefore, a photoelectric conversion layer containing a perovskite compound uniformly and having an improved film quality is obtained, and as a result, the power generation efficiency of the solar cell is improved.

In the present disclosure, the poor solvent is a solvent having a solubility of the perovskite compound lower than that of at least the solvent of the precursor solution, and more preferably, a solvent capable of substantially dissolving the perovskite compound. The poor solvent refers to, for example, a solvent in which the solubility of the perovskite compound at 25° C. (weight ratio of solute to solvent 100 g) is usually less than 1.0% by weight, preferably less than 0.1% by weight, and more preferably less than 0.01% by weight. As the poor solvent, for example, a solvent having a relative permittivity of 20 or less can be used. The poor solvent is not particularly limited, and examples thereof include substituted aliphatic hydrocarbons such as dichloromethane and chloroform. Examples of the poor solvent include aromatic compounds such as toluene, benzene, chlorobenzene, and tetralin. Examples of the poor solvent include ethers such as diethyl ether and tetrahydrofuran (THF). Examples of the poor solvent include alcohols having 3 or more carbon atoms (e.g., 1-propanol, 2-propanol, and 1-butanol). Examples of the poor solvent include hydrocarbons having 4 to 10 carbon atoms; and organic solvents such as acetic acid. In the present disclosure, the aromatic compound also includes a compound containing a part of an aromatic ring. The poor solvent may be used singly or in combination of two or more of these solvents. In one embodiment, when the poor solvent is applied by the inkjet method, the poor solvent is preferably a solvent having a boiling point of 100° C. or higher from the viewpoint of suppressing clogging of the inkjet nozzle. In a preferred embodiment, the poor solvent is one or more selected from solvents having a relative permittivity of 20 or less and a boiling point of 100° C. or more. Examples of such a poor solvent include, but are not limited to, toluene, chlorobenzene, tetralin, 1-butanol, and acetic acid. In one embodiment, the poor solvent is tetralin and 2-propanol. In addition, when a solvent having a relative permittivity of 5 or more and 20 or less (preferably a solvent having a relative permittivity of 10 or more and 20 or less) is used as the poor solvent, the uniformity of the photoelectric conversion layer is improved.

In the poor solvent applying step, the poor solvent is applied to the coating surface as droplets. In one embodiment, the coating surface is the surface of the first carrier transport layer (e.g., hole transport layer or electron transport layer) as described above for the precursor solution application step. Application of the poor solvent as droplets can be performed by, for example, a spin coating method, an ink jet method, and a spray method, and an ink jet method and a spray method are preferable, and an ink jet method is more preferable. In a preferred embodiment, the precursor solution and the poor solvent are applied by an ink jet method or a spray method, more preferably by an ink jet method.

The poor solvent applying step can be performed under a dry air atmosphere or an inert gas atmosphere, similarly to the precursor solution applying step.

In the poor solvent applying step, the temperature of the poor solvent is usually 25° C. or higher, and preferably 40° C. or higher. The temperature of the poor solvent is usually 60° C. or lower, and preferably 50° C. or lower. The temperature of the poor solvent is preferably the same as the temperature of the precursor solution. In the poor solvent applying step, the temperature of the coating surface is usually 20° C. or higher, preferably 40° C. or higher, more preferably 60° C. or higher, and is usually 80° C. or lower, preferably 70° C. or lower, as described above for the precursor solution applying step. In a preferred embodiment, the temperature of the poor solvent is 40° C. or higher and the temperature of the application surface is 60° C. or higher. In this embodiment, high quality perovskite crystals are formed.

In the poor solvent application step, the poor solvent is applied to the droplets of the precursor solution as droplets until the droplets of the precursor solution adhered to the application surface combine with the droplets of the other precursor solution. The applied poor solvent droplets come into contact with and bind to the precursor solution droplets. The timing of application of the poor solvent is not particularly limited as long as it is before the droplets of the precursor solution combine with the droplets of the other precursor solution. The timing of application of the poor solvent may be concurrent with the application of the precursor solution, or may be applied, for example, at an interval of about 0.1 seconds to 1.0 seconds from the application of the precursor solution. In the present disclosure, “until a droplet of a precursor solution is combined with a droplet of another precursor solution” means until a droplet of the precursor solution comes into contact with a droplet of another precursor solution. The application of the poor solvent may be performed such that a droplet of the applied poor solvent comes into contact with a droplet of the precursor solution, or such that a droplet of the poor solvent adhering to the application surface spreads and comes into contact with a droplet of the precursor solution.

As the application conditions of the poor solvent, the conditions normally used can be appropriately selected except that the poor solvent is applied as a droplet until the droplet of the precursor solution adhered to the application surface is combined with the droplet of the other precursor solution.

The manufacturing method of the present disclosure may include an annealing treatment step after the poor solvent application step. The photoelectric conversion layer is formed by performing the annealing treatment.

The annealing treatment is usually a treatment of heating the coating film at a temperature of 70° C. or higher and 200° C. or lower.

Note that the manufacturing method of the present disclosure may include a drying step between the poor solvent applying step and the annealing step. In the drying step, the solvent is removed from the coating film using a known drying method such as a method of heating, a method of blowing a drying gas, or a method of evacuating, for example. When the manufacturing method of the present disclosure does not include a drying step, it may be understood that the annealing step is a process in which the annealing treatment and the drying treatment are performed in a one-step operation.

A perovskite-type solar cell obtained by the manufacturing method of the present disclosure (hereinafter, also referred to as a solar cell of the present disclosure) has a photoelectric conversion layer containing a perovskite compound.

In one embodiment, the solar cell of the present disclosure includes a substrate, a first electrode layer, a first carrier transport layer, a photoelectric conversion layer containing a perovskite compound, a second carrier transport layer, and a second electrode layer in this order.

In one embodiment, the first carrier transport layer is a hole transport layer (Hole Transport Layer: HTL) and the second carrier transport layer is an electron transport layer (Electron Transport Layer: ETL). In another embodiment, the first carrier transport layer is an electron transport layer and the second carrier transport layer is a hole transport layer.

The first electrode layer and the second electrode layer may be an anode or a cathode. In one embodiment, the first electrode layer is an anode, the first carrier transport layer is a hole transport layer, the second electrode layer is a cathode, and the second carrier transport layer is an electron transport layer. In another embodiment, the first electrode layer is a cathode, the first carrier transport layer is an electron transport layer, the second electrode layer is an anode, and the second carrier transport layer is a hole transport layer.

In a first embodiment of the solar cell of the present disclosure, the solar cell includes a substrate, a first electrode layer, an electron transport layer, a photoelectric conversion layer, a hole transport layer, and a second electrode layer in this order.

In a second embodiment of the solar cell of the present disclosure, the solar cell includes a substrate, a first electrode layer, a hole transport layer, a photoelectric conversion layer, an electron transport layer, and a second electrode layer in this order.

The substrate is a plate-like or film-like member. The material of the substrate is not particularly limited. Examples of the material of the substrate include inorganic materials such as glass, organic materials such as polyethylene, polyethylene terephthalate, polyethylene naphthalate, polyimide, polyamide, polyamideimide, liquid crystal polymer, and cycloolefin polymer, and metal materials such as stainless steel and silicon. The material of the substrate is preferably glass.

The substrate may be transparent or opaque. When light is incident from the surface of the substrate, a transparent substrate is used. As the transparent substrate, a substrate made of glass, polyethylene terephthalate, polyethylene naphthalate, polyimide, polyamide, polyamideimide, or cycloolefin polymer can be used. Also, if light is incident from the opposite side of the substrate, the substrate can be opaque. The thickness of the board is usually several tens of micrometers to several mm.

As a material of the first electrode layer and the second electrode layer, a material known as an electrode of a solar cell can be used, such as a metallic material such as aluminum (Al), silver (Ag), or gold (Au), a transparent conductive film such as indium tin oxide (ITO), indium zinc oxide (IZO), aluminum-doped zinc oxide (AZO), or fluorine-doped tin oxide (FTO), or a carbon nanotube. The first electrode layer and the second electrode layer are preferably made of ITO, IZO and FTO. The thicknesses of the first electrode layer and the second electrode layer are usually 50 nm to 500 nm.

The hole transport layer has a function of transporting holes generated by photoelectric conversion in the photoelectric conversion layer to the first electrode layer or the second electrode layer. As the material of the hole transport layer, a known organic material or inorganic material that can be used for the hole transport layer can be used. The organic material is not particularly limited. Examples of the organic compound include 2,2′,7,7′-tetrakis-(N,N-di-4-methoxyphenylamino)-9,9′-spirobifluorene (Spiro-OMeTAD), polyethylenedioxythiophene: polystyrenesulfonic acid (PEDOT:PSS), poly [bis(4-phenyl) (2,4,6-trimethylphenyl)amine] (PTAA), [2-(3,6-dimethoxy-9H-carbazole-9H-yl)ethyl]phosphonic acid (MeO-2PACz), and the like. The inorganic material is not particularly limited, and examples thereof include nickel oxide, copper oxide, cobalt oxide, and copper iodide. In a first embodiment of the photovoltaic cell of the disclosure, the hole-transporting layers are preferably Spiro-OMeTAD, PTAA and nickel-oxide. In the second embodiment of the photovoltaic cell of the disclosure, the hole-transporting layers are preferably PEDOT:PSS, PTAA and nickel-oxide. The thickness of the hole-transport layers is usually from 1 nm to 1000 nm.

The electron transport layer has a function of transporting electrons generated by photoelectric conversion in the photoelectric conversion layer to the first electrode layer or the second electrode layer. As the material of the electron transport layer, a known organic material or inorganic material that can be used for the electron transport layer can be used. Examples of the organic material include, but are not limited to, fullerene compounds, phenanthroline derivatives (for example, bathocuproine), polyethylencimines, and the like. Examples of the fullerene compound include a fullerene and a derivative obtained by adding a substituent to a fullerene. Examples of fullerenes include C60 fullerenes and C70 fullerenes. Examples of the derivative obtained by adding a substituent to fullerene include methyl [6,6]-phenyl-C₆₁ butyrate and methyl [6,6]-phenyl-C₇₁ butyrate. [6,6]-Phenyl-C₆₁ butyrate is also referred to as PCBM or [60]PCBM; [6,6]-Phenyl-C₇₁ butyrate is also referred to as PCBM or [70]PCBM. Examples of the inorganic material include titanium oxide, tin oxide, and zinc oxide. In a first embodiment of the photovoltaic cell of the disclosure, the electron-transporting layer is preferably made of fullerene, PCBM, bathocuproine, polyethyleneimines, titanium oxide and tin oxide. In the second embodiment of the photovoltaic cell of the present disclosure, the electron-transporting layer is preferably made of fullerene, PCBM, vasoxoproin, or polyethyleneimine. The thickness of the electron-transport layers is usually from 1 nm to 1000 nm.

The photoelectric conversion layer contains a perovskite compound, preferably contains a perovskite compound as a main component, and more preferably consists of a perovskite compound. The content of the perovskite compound in the photoelectric conversion layer is usually 60% by weight or more, preferably 80% by weight or more, more preferably 90% by weight or more, particularly preferably 95% by weight or more, and most preferably 100% by weight. The perovskite compound is as described above for the manufacturing method of the present disclosure. Since the film quality of the photoelectric conversion layer is improved, the solar cell of the present disclosure is excellent in power generation efficiency. The thickness of the photoelectric converter layers is usually 50 nm to 1000 nm, more preferably 200 nm to 600 nm.

In the solar cell of the present disclosure, a layer other than the photoelectric conversion layer can be formed, for example, by forming a film by a known method.

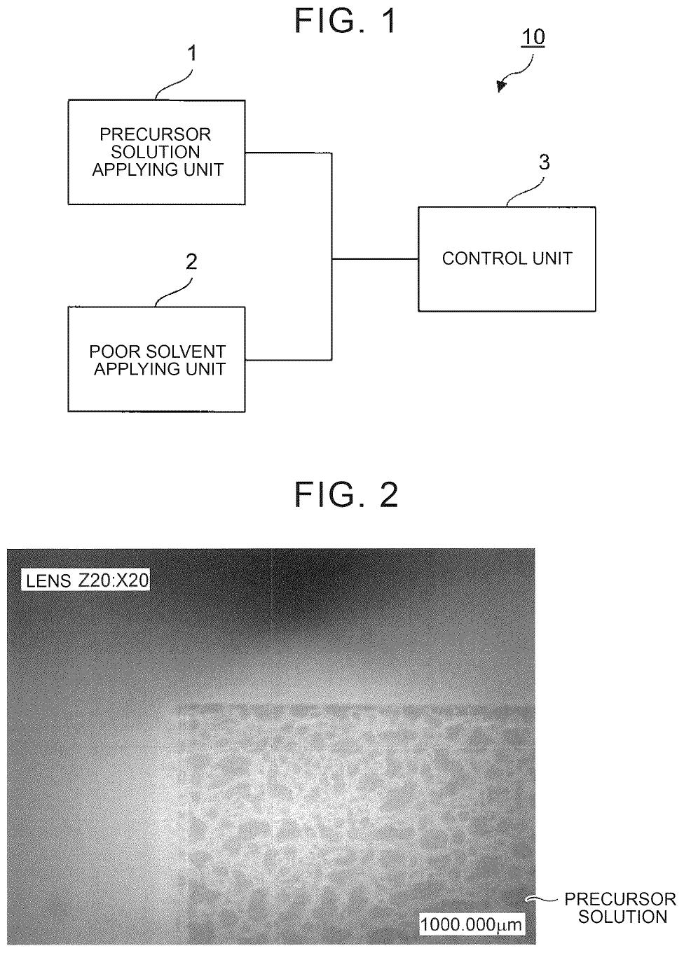

The present disclosure also relates to an apparatus for manufacturing a perovskite-type solar cell. The manufacturing apparatus of the present disclosure may be a manufacturing apparatus for carrying out the manufacturing method of the perovskite-type solar cell of the present disclosure. FIG. 1 is a schematic diagram of an embodiment of a manufacturing apparatus of the present disclosure. As shown in FIG. 1, the apparatus 10 for manufacturing a perovskite-type solar cell of the present disclosure includes a precursor solution applying unit 1, a poor solvent applying unit 2, and a control unit 3 that controls the precursor solution applying unit 1 and the poor solvent applying unit 2.

The precursor solution applying unit 1 applies the precursor solution of the perovskite compound as a droplet on the basis of control by the control unit 3 (for example, a control signal supplied from the control unit 3). The precursor solution applying unit 1 includes, for example, a storage unit for a precursor solution, a discharge unit for a precursor solution, and a reception unit for a control signal supplied from the control unit 3.

The poor solvent applying unit 2 applies the poor solvent as droplets based on control by the control unit 3 (for example, a control signal supplied from the control unit 3). The poor solvent applying unit 2 includes, for example, a storage unit for poor solvent, a discharge unit for poor solvent, and a reception unit for a control signal supplied from the control unit 3.

The control unit 3 controls the precursor solution applying unit 1 and the poor solvent applying unit 2 so that the poor solvent is applied as droplets until the droplets of the precursor solution adhering to the application surface are combined with the droplets of the other precursor solution. For example, the control unit 3 supplies a control signal to the precursor solution applying unit 1 and the poor solvent applying unit 2. In one embodiment, the control unit 3 is a control computer.

The manufacturing apparatus 10 of the present disclosure is preferably used in the manufacturing method of the present disclosure in which the precursor solution and the poor solvent are applied by an ink jet method or a spray method. The manufacturing apparatus 10 of the present disclosure is more preferably used in the manufacturing method of the present disclosure in which the precursor solution and the poor solvent are applied by the inkjet method. When the manufacturing apparatus 10 of the present disclosure is used in the manufacturing method of the present disclosure in which the precursor solution and the poor solvent are applied by the inkjet method, the manufacturing apparatus 10 of the present disclosure may include an inkjet head and a control unit 3 that controls the inkjet head. The inkjet head includes a precursor solution applying unit 1 and a poor solvent applying unit 2. The control unit 3 is, for example, a control computer. In this embodiment, the application of the precursor solution and the poor solvent by the inkjet method may be performed by fixing the application surface and moving the inkjet head, or may be performed by fixing the inkjet head and moving the application surface.

Hereinafter, the present disclosure will be described in more detail with reference to Examples. However, the technical scope of the present disclosure is not limited to these examples.

### Example 1

Glass plates with indium-tin-oxide (ITO) films were used as substrates. In addition, a solution was prepared in which a three-way CsFAMAPbI₃ was included in a solvent of N,N-dimethylformamide (DMF), dimethylsulfoxide (DMSO) and γ-butyrolactone (GBL) (DMF:DMSO:GBL (volume ratio)=28:26:46), along with 1-hexyl-3-methymidazorium chloride (HMImCl). This was used as a precursor solution. Tetraline was used as a poor solvent.

Industrial inkjet heads (MH5420 manufactured by Ricoh Co., Ltd.) were filled with precursor solutions and poor solvent. Precursor solutions and poor solvents were simultaneously applied onto ITO film of the substrate by an ink-jet method to obtain a wet film. The application conditions of the precursor solution and the poor solvent were as follows: ink jet head temperature: 54° C., frequency: 5 kHz, X pitch: 300, Y pitch: 600, drop: 1, number of scans: 1, substrate temperature: room temperature (about 25° C.). In Example 1, the poor solvent was applied as a droplet and the poor solvent was bound to the droplets of the precursor solution before the droplets of the precursor solution bound to the droplets of the other precursor solution.

### Comparative Example 1

The precursor solution was applied onto ITO film of the substrate by an ink jet method, and the droplets of the precursor solution were bonded and spread to form a film (after about 10 seconds), and then the poor solvent was applied by an ink jet method (sequentially applied) to obtain a wet film. The application conditions of the precursor solution and the poor solvent were the same as in Example 1.

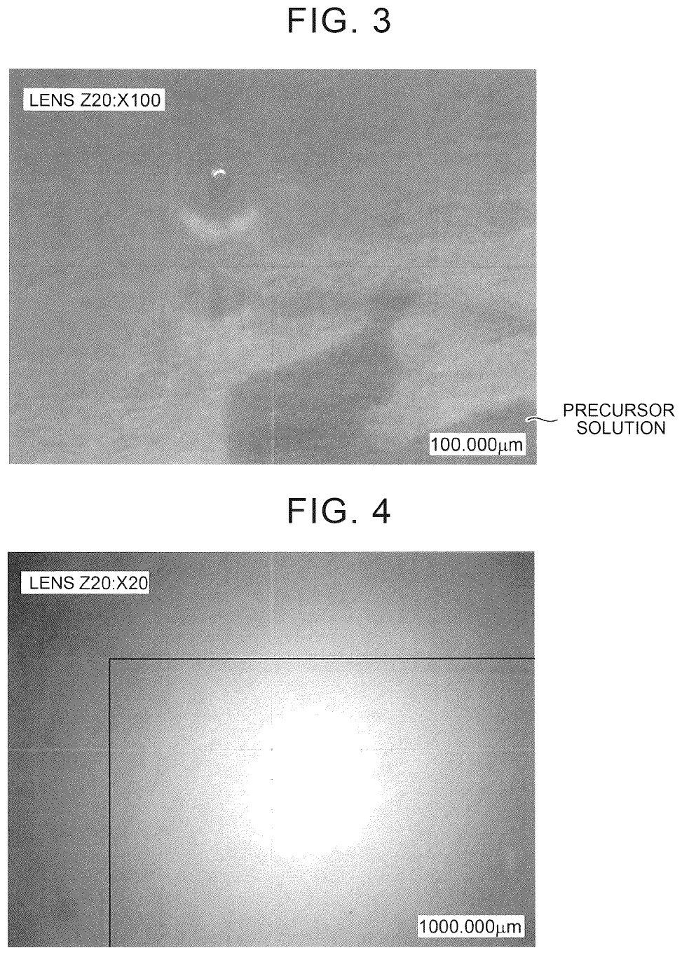

The wet films obtained in Example 1 (simultaneous application) and Comparative Example 1 (sequential application) were observed by an optical microscope. FIG. 2 shows an appearance photograph of the wet film of Example 1. FIG. 3 shows an appearance photograph of the wet film of Comparative Example 1. As shown in FIG. 2, when the precursor solution and the poor solvent were co-applied, the droplets of the precursor solution and the poor solvent were sufficiently mixed and the precursor solution was uniformly dispersed. On the other hand, as shown in FIG. 3, when the precursor solution and the poor solvent were sequentially applied, the spread precursor solution and the poor solvent were completely separated from each other.

When the wet film obtained in Example 1 was heated at 100° C., a film containing a perovskite compound was formed. It was confirmed that the formed film contained the perovskite compound by measurement of transmission absorption spectrum, measurement by X-ray diffractometry (XRD), and the like. In Comparative Example 1, the precursor solution and the poor solvent were completely separated from each other, and thus the obtained wet film could not be formed into a film.

### Example 2

In the same manner as in Example 1, except that the poor solvent was changed from tetralin to 2-propanol and the ink jet head temperature was changed to 40° C. and the substrate temperature was changed to 60° C., the precursor solution and the poor solvent were simultaneously applied onto ITO film of the substrate by the ink jet method to obtain a wet film. FIG. 4 shows an appearance photograph of the wet film of Example 2. In FIG. 4, a line was drawn on the outer edge of the substrate. As shown in FIG. 4, by changing the poor solvent from tetralin to 2-propanol and adjusting the coating conditions, it was confirmed that the precursor solution was applied more uniformly in the wet film. In the wet film of Example 2, the precursor solution was uniformly applied to the same extent as in the case where only the precursor solution was applied to the substrate.

What is claimed is:

1. A manufacturing method for manufacturing a perovskite-type solar cell, the manufacturing method comprising:
applying a precursor solution of a perovskite compound as droplets; and
applying a poor solvent as droplets, until droplets of the precursor solution adhering to an application face bind to droplets of another precursor solution.

2. The manufacturing method according to claim 1, further comprising:
applying the precursor solution and the poor solvent by an inkjet method or a spray method.

3. The manufacturing method according to claim 1, wherein the poor solvent is one type or more selected from solvents of which a relative permittivity is 20 or lower and also a boiling point is 100° C. or higher.

4. The manufacturing method according to claim 1, wherein a temperature of the precursor solution is 40° C. or higher, and a temperature of the application face is 60° C. or higher.

5. A manufacturing apparatus for manufacturing a perovskite-type solar cell, the manufacturing apparatus comprising:
a precursor solution applying unit that applies a precursor solution of a perovskite compound as droplets;
a poor solvent applying unit that applies a poor solvent as droplets; and
a control unit that controls the precursor solution applying unit and the poor solvent applying unit such that the poor solvent is applied as droplets, until droplets of the precursor solution adhering to an application face bind to droplets of another precursor solution.
